(19) United States
(12) Patent Application Publication
(10) Pub. No.: US 2024/0153811 A1
(43) Pub. Date: May 9, 2024

(54) SUBSTRATE PROCESSING APPARATUS AND METHOD FOR FABRICATING SEMICONDUCTOR DEVICE USING THE SAME

(71) Applicant: Samsung Electronics Co., Ltd., Suwon-si (KR)

(72) Inventors: Sang Duk HWANG, Suwon-si (KR); Jai Hoon KANG, Suwon-si (KR); Young Joon KIM, Suwon-si (KR)

(73) Assignee: Samsung Electronics Co., Ltd., Suwon-si (KR)

(21) Appl. No.: 18/202,052

(22) Filed: May 25, 2023

(30) Foreign Application Priority Data
Nov. 7, 2022 (KR) 10-2022-0147057
Jan. 26, 2023 (KR) 10-2023-0009831

(51) Int. Cl. H01L 21/687; G03F 7/16; H01L 21/67

(52) U.S. Cl. CPC H01L 21/68764; G03F 7/162; H01L 21/6715

(57) ABSTRACT

A substrate processing method includes placing a substrate on a spin chuck and rotating the spin chuck around a central axis extending in a first direction; and applying a processing liquid onto the substrate through a nozzle. The nozzle includes a pipe extending in the first direction and through which the processing liquid moves, and a housing surrounding the pipe, and the pipe includes one or more first lower pipe sections, each of whose width in a second direction intersecting the first direction increases and then decreases in a direction toward the substrate.

### CROSS-REFERENCE TO RELATED APPLICATION

This application claims priority to Korean Patent Application No. 10-2022-0147057 filed on Nov. 7, 2022 and No. 10-2023-0009831 filed on Jan. 26, 2023 in the Korean Intellectual Property Office, and all the benefits accruing therefrom under 35 U.S.C. 119, the contents of each of which in its entirety are herein incorporated by reference.

### BACKGROUND

### 1. Technical Field

The present disclosure relates to a substrate processing apparatus with improved efficiency and a method for fabricating a semiconductor device using the same.

### 2. Description of the Related Art

A semiconductor device may be fabricated through a plurality of unit processes. The unit processes may include, for example, a thin film deposition process, a photolithography process, an etching process, and a cleaning process. Among them, the photolithography process may include a photoresist application process, a baking process, an exposure process, and/or a development process.

### SUMMARY

Aspects of the present disclosure provide a substrate processing apparatus with improved efficiency.

Aspects of the present disclosure also provide a method for fabricating a semiconductor device using a substrate processing apparatus with improved efficiency.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate processing apparatus includes a spin chuck configured to accommodate a substrate and rotate around a central axis extending in a first direction; and a nozzle for applying a processing liquid onto the substrate. The nozzle includes a pipe extending in the first direction and through which the processing liquid moves, and a housing surrounding the pipe, and the pipe includes one or more first lower pipe sections, each of whose width in a second direction intersecting the first direction increases and then decreases in a direction toward the substrate.

According to another aspect of the present disclosure, a substrate processing apparatus includes a spin chuck configured to accommodate a substrate and rotate the substrate; and a nozzle connected to apply a processing liquid onto the substrate. The nozzle includes a passage through which the processing liquid moves, and a housing surrounding the passage. The passage includes a plurality of lower passage sections, each of the plurality of lower passage sections includes an uppermost end into which the processing liquid is introduced, a lowermost end through which the processing liquid is discharged, and a central opening between the uppermost and lowermost ends, and a width of the central opening is greater than a width of the uppermost end and is greater than a width of the lowermost end.

According to another aspect of the present disclosure, a substrate processing apparatus includes a chamber defining a processing space, a spin chuck disposed in the chamber to accommodate a substrate and to be rotatable about an axis in a first direction, a nozzle connected to apply a photoresist onto the substrate, and a photoresist supply portion for supplying the photoresist to the nozzle from a photoresist supply source. The nozzle includes a pipe extending in the first direction and through which the photoresist moves, and a housing surrounding the pipe. The pipe includes one or more first lower pipe sections whose widths in a second direction intersecting the first direction increase and then decrease toward the substrate. Each first lower pipe section includes a first portion and a second portion on the first portion, a width of the first portion in the second direction increasing as a distance from the substrate increases, and a width of the second portion in the second direction decreasing as a distance from the substrate increases. A first height of the first portion in the first direction is greater than a second height of the second portion in the first direction, a width of an uppermost end of the first portion is equal to a width of a lowermost end of the second portion, and a width of an uppermost end of the pipe is smaller than a width of a lowermost end of the pipe.

According to another aspect of the present disclosure, a method for fabricating a semiconductor device includes loading a substrate into a substrate processing apparatus, and processing the substrate using the substrate processing apparatus, wherein the processing of the substrate includes applying a photoresist onto the substrate using a nozzle disposed in the substrate processing apparatus, wherein the nozzle includes a passage extending in a first direction and through which the photoresist moves, and a housing surrounding the passage, and wherein the passage includes one or more lower passage sections whose widths in a second direction intersecting the first direction increase and then decrease toward the substrate.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an illustrative view for describing a substrate processing apparatus according to some exemplary embodiments of the present disclosure.

FIG. 2 is a plan view illustrating the substrate processing apparatus of FIG. 1.

FIG. 3 is a side view illustrating the substrate processing apparatus of FIG. 1.

FIG. 4 is an illustrative perspective view for describing a spin unit of FIG. 1.

FIG. 5 is an illustrative cross-sectional view for describing the spin unit of FIG. 1.

FIG. 6 is an enlarged view for describing a nozzle of FIG. 5.

FIG. 7 is an enlarged view for describing a first lower pipe of FIG. 6.

FIGS. 8 to 14 are illustrative views for describing a first lower pipe according to some other exemplary embodiments.

FIGS. 15 to 17 are views for describing a nozzle according to some other exemplary embodiments.

FIG. 18 is a flowchart for describing a method for fabricating a semiconductor device according to some exemplary embodiments.

FIGS. 19 to 21 are intermediate step views for describing the method for fabricating the semiconductor device according to some exemplary embodiments.

FIG. 22 is an illustrative graph illustrating a speed of a photoresist according to a distance of a pipe.

### DETAILED DESCRIPTION OF THE EMBODIMENTS

Terms “first”, “second”, “upper portion, “lower portion”, and the like are used herein to describe various elements or components, but these elements or components are not limited by these terms. These terms are used only to distinguish one element or component from another element or component. Therefore, a first element or component mentioned below may be a second element or component within the technical spirit of the present disclosure. In addition, a lower element or component mentioned below may be an upper element or component within the technical spirit of the present disclosure, depending on the context in which it is described. Also, the various drawings are not necessarily drawn to scale, and relative size and dimensions of the various components described herein may vary from those depicted in the drawings.

Hereinafter, exemplary embodiments of the present disclosure will be described with reference to the accompanying drawings.

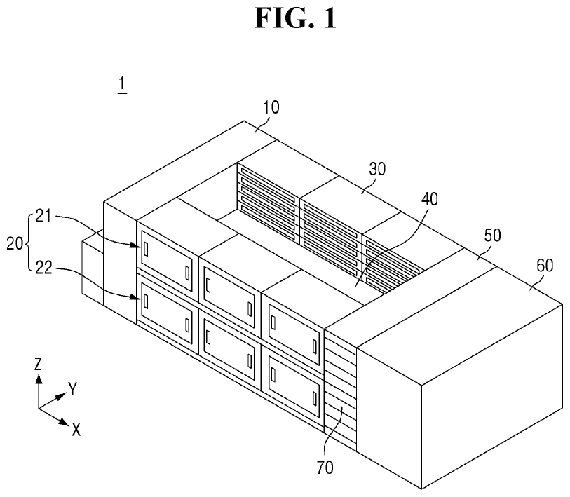

Hereinafter, a substrate processing apparatus according to some exemplary embodiments will be described with reference to FIGS. 1 to 7.

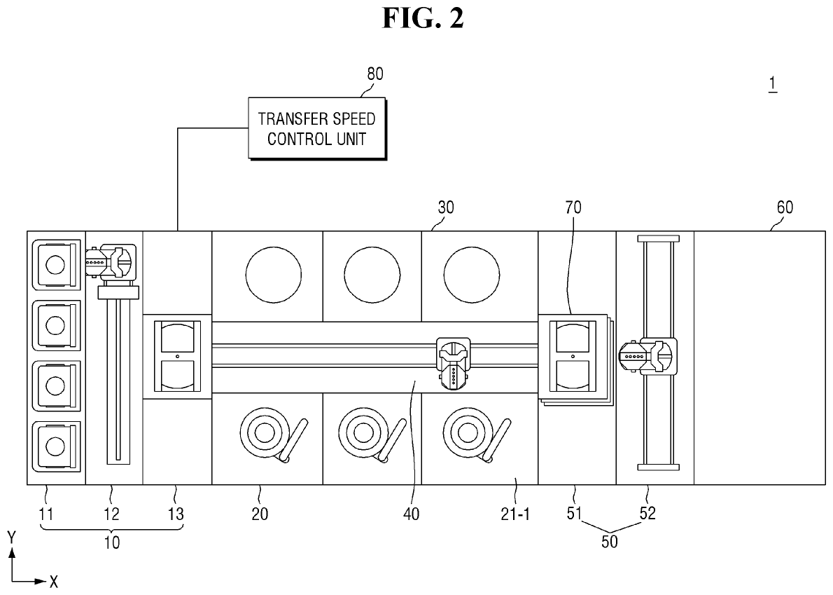

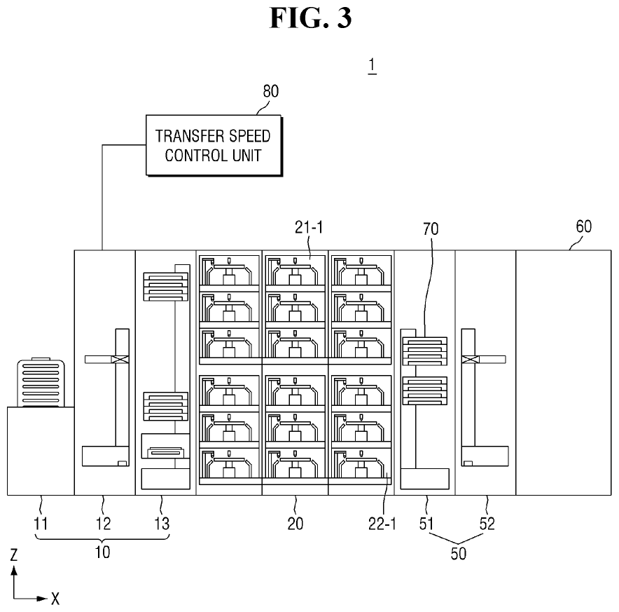

FIG. 1 is an illustrative view for describing a substrate processing apparatus according to some exemplary embodiments of the present disclosure. FIG. 2 is a plan view illustrating the substrate processing apparatus of FIG. 1. FIG. 3 is a side view illustrating the substrate processing apparatus of FIG. 1.

Referring to FIGS. 1 to 3, a substrate processing apparatus 1 includes an index unit 10, a process processing unit (not illustrated), an interface unit 50, an exposure unit 60, a humidity control unit 70, and a transfer speed control unit 80. The process processing unit (not illustrated) includes a spin unit 20, a bake unit 30, and a transfer unit 40.

The index unit 10 may include a plurality of load ports 11, an index robot 12, and a first buffer module 13.

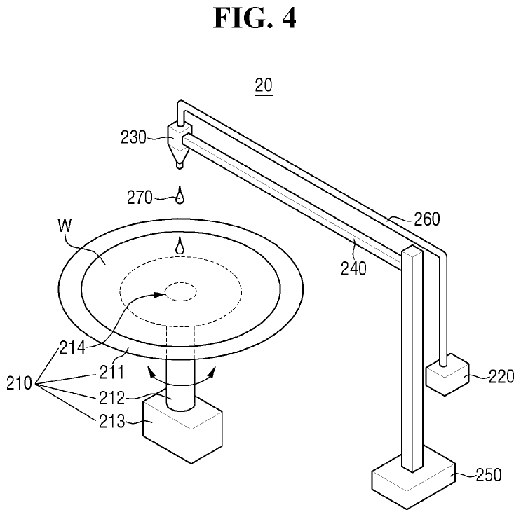

The load port 11 has a mounting table on which a cassette containing a substrate is placed. The load port 11 may include a plurality of mounting tables, and the plurality of mounting tables may be disposed in a line along a y direction Y. It is illustrated in FIG. 4 that the load port 11 includes four mounting tables, but the exemplary embodiment is not limited thereto. The number of mounting tables included in the load port 11 may be changed according to exemplary embodiments.

The index robot 12 transfers a substrate W between the load port 11 and the first buffer module 13. The index robot 12 may include a frame, a transfer robot, and a guide rail. The frame is generally provided in a shape of a rectangular parallelepiped with an empty interior, and is disposed between the load port 11 and the first buffer module 13. The transfer robot and guide rail are disposed in the frame. The transfer robot may include a structure capable of four-axis driving so as to be movable and rotatable in an x direction X, a y direction Y, and a z direction Z.

The first buffer module 13 may be provided in a shape of a rectangular parallelepiped with an empty interior for temporarily storing a plurality of substrates W. The first buffer module 13 may be disposed between the index robot 12 and the process processing unit including the spin unit 20, the bake unit 30, and the transfer unit 40.

The spin unit 20 may include a coating unit 21 that performs a process of coating a photoresist on the substrate W before an exposure process, and a developing unit 22 that performs a process of developing the substrate W after the exposure process. The coating unit 21 and the developing unit 22 may be disposed to be partitioned into layers from each other. For example, the coating unit 21 may be disposed on an upper side of the developing unit 22. As another example, the coating unit 21 may be disposed on a lower side of the developing unit 22.

The coating unit 21 performs a process of coating a photosensitive solution, such as a photoresist, on the substrate W. For example, the process may be a spin coating process, and the process of coating may include coating the entire surface of the substrate W with the photoresist. The coating unit 21 may include a plurality of coating chambers 21-1. The coating chambers 21-1 of the coating unit 21 may be continuously disposed along the x direction X and may be stacked and disposed along the z direction Z. The plurality of coating chambers 21-1 may all have the same structure. The types of photoresist used in each of the coating chamber 21-1 may be different from each other.

It is illustrated in FIGS. 2 and 3 that three coating chambers 21-1 are disposed in each of the x direction X and the z direction Z, but the exemplary embodiment is not limited thereto. The number of coating chambers 21-1 disposed along the x direction X and the z direction Z may be variously modified according to exemplary embodiments.

The developing unit 22 performs a developing process of removing a portion of the photoresist by supplying a developer to obtain a pattern on the substrate W. The developing unit 22 may remove an area of the photoresist on the substrate W irradiated with light. Depending on the type of photoresist optionally used, only an area of the photoresist that is not irradiated with light may be removed.

The developing unit 22 may include a plurality of developing chambers 22-1. The developing chambers 22-1 of the developing unit 22 may be continuously disposed along the x direction X and may be stacked and disposed along the z direction Z. The plurality of developing chambers 22-1 may all have the same structure. The types of photoresist used in each of the developing chamber 22-1 may be different from each other.

It is illustrated in FIGS. 2 and 3 that three developing chambers 22-1 are disposed in each of the x direction X and the z direction Z, but the exemplary embodiment is not limited thereto. The number of developing chambers 22-1 disposed along the x direction X and the z direction Z may be variously modified according to exemplary embodiments.

The bake unit 30 performs a heat treatment process for heating or cooling the substrate W. The bake unit 30 may perform a pre-bake process of heating the substrate W to a predetermined temperature before coating the photoresist to remove organic matter or moisture from a surface of the substrate W, a soft bake process performed after coating the photoresist on the substrate W, a post-bake process of heating the substrate W before the developing process is performed, a hard bake process of heating the substrate W after the developing process is performed, a cooling process of cooling the heated wafer after each bake process, and the like.

The bake unit 30 may include a plurality of baking chambers. The baking chambers of the bake unit 30 may be continuously disposed along the x direction X and may be stacked and disposed along the z direction Z. It is illustrated in FIG. 2 that three baking chambers are disposed along the x direction X and six baking chambers are stacked along the z direction Z, but the exemplary embodiment is not limited thereto. The number of baking chambers disposed along the x direction X and the z direction Z may be variously modified according to exemplary embodiments.

The baking chamber has a cooling plate or a heating plate. The cooling plate may be provided with a cooling means such as cooling water or a thermoelectric element. The heating plate may be provided with heating means such as a heating wire or a thermoelectric element. Some of the plurality of baking chambers may have only the cooling plate, and other baking chambers may have only the heating plate. In addition, one baking chamber may have both the cooling plate and the heating plate.

The transfer unit 40 is disposed parallel to the first buffer module 13 and a second buffer module 51 in the x direction X. A process processing unit robot and a guide rail are positioned in the transfer unit 40. The transfer unit 40 has a substantially rectangular shape. The process processing unit robot transfers the substrate W between the first buffer module 13, the coating unit 21, the developing unit 22, the bake unit 30, and the second buffer module 51. The guide rail extends along the x direction X. The guide rail guides the process processing unit robot so that the process processing unit robot linearly moves in the x direction X.

The spin unit 20, the transfer unit 40, and the bake unit 30 are disposed along they direction Y. For example, the coating unit 21 and the developing unit 22 are positioned to face the bake unit 30 with the transfer unit 40 interposed therebetween.

The interface unit 50 may transfer the substrate W between the exposure unit 60 and the process processing unit (not illustrated) including the spin unit 20, the bake unit 30, and the transfer unit 40. The interface unit 50 may include a second buffer module 51 and an interface robot 52.

The second buffer module 51 may temporarily store the substrate W. The second buffer module 51 may include a plurality of chambers (corresponding to a “first buffer chamber” and a “second buffer chamber”) accommodating the substrate W. The first buffer chamber may temporarily store the substrate W transferred from the process processing unit (e.g., the coating unit) to the exposure unit 60. The second buffer chamber may temporarily store the substrate W transferred from the exposure unit 60 to the process processing unit (e.g., the bake unit).

A shape in which the first buffer chamber and the second buffer chamber are disposed in the second buffer module 51 may be modified according to exemplary embodiments. For example, the first buffer chamber and the second buffer chamber may be stacked in the second buffer module 51 along the z direction Z.

As another example, the first buffer chamber and the second buffer chamber may be disposed side by side in the x direction X or the y direction Y. In this case, a plurality of first buffer chambers may be stacked to form a first buffer tower, and a plurality of second buffer chambers may be stacked to form a second buffer tower. That is, the first buffer tower and the second buffer tower may be disposed side by side in the x direction X or the y direction Y.

The second buffer module 51 may include a chamber in which the substrate W is not accommodated. In addition, the humidity control unit 70 may be disposed in the second buffer module 51. This will be described in detail below.

The interface robot 52 may transfer the substrate W between the second buffer module 51 and the exposure unit 60.

The exposure unit 60 may irradiate the substrate W on which a photoresist film is formed with light using a stepper to form a circuit pattern on the substrate W.

The humidity control unit 70 may control an amount of moisture to which the substrate W is exposed so that a performance of the substrate W is not reduced when the substrate W passes through the humidity control unit 70. The humidity control unit 70 may supply steam to increase a total amount of moisture to which the substrate W is exposed in the substrate processing apparatus 1.

In some exemplary embodiments, the humidity control unit 70 may be disposed in the second buffer module 51 of the interface unit 50. For example, the humidity control unit 70 may be disposed in the plurality of chambers of the second buffer module 51. For example, the humidity control unit 70 may be disposed to be stacked with the first buffer chamber and the second buffer chamber of the second buffer module 51 in the z direction Z. As another example, the humidity control unit 70 may be disposed between the first buffer chamber and the second buffer chamber of the second buffer module 51 in the x direction X or the y direction Y.

In this case, the humidity control unit 70 may control the total amount of moisture to which the substrate W provided from the spin unit 20 to the exposure unit 60 is exposed. Compared to before passing through the humidity control unit 70, the amount of moisture to which the substrate W is exposed sharply increases when the substrate W passes through the humidity control unit 70.

The transfer speed control unit 80 may control a speed at which the index robot 12, the transfer unit 40, and the interface robot 52 transfer the substrate W in the substrate processing apparatus 1. For example, when the substrate W is transferred from the spin unit 20 to the bake unit 30 through the transfer unit 40, the transfer speed control unit 80 may control a transfer speed of the substrate W.

Hereinafter, a spin unit according to some exemplary embodiments will be described in more detail with reference to FIGS. 4 to 7.

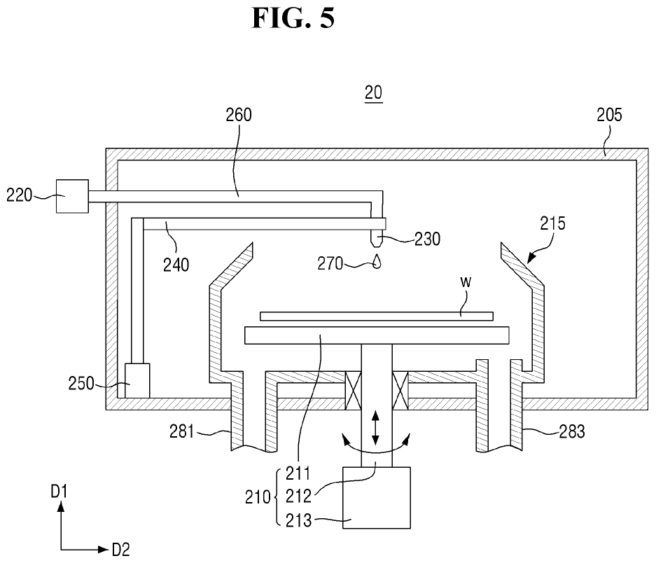

FIG. 4 is an illustrative perspective view for describing a spin unit of FIG. 1. FIG. 5 is an illustrative cross-sectional view for describing the spin unit of FIG. 1.

Referring to FIGS. 4 and 5, the spin unit 20 according to some exemplary embodiments may include a chamber 205, a spin chuck 210, a recovery cup 215, a photoresist supply portion 220, a nozzle 230, a nozzle arm 240, an elevating mechanism 250, and a photoresist pipe 260.

The chamber 205 may define a processing space. The processing space is a space in which the substrate W is processed. For example, a process of coating a photoresist on the substrate W may be performed in the chamber 205. The photoresist may be applied onto the substrate W in the chamber 205. The chamber may have chamber walls, a chamber floor, and a chamber ceiling, which form a chamber body.

The spin chuck 210 may be disposed within the chamber 205. The spin chuck 210 may accommodate the substrate W. A portion of the spin chuck 210 may also be disposed outside the chamber 205, but the present disclosure is not limited thereto.

In some exemplary embodiments, the spin chuck 210 may include a support plate 211, an elevating portion 212, a driving portion 213, and a vacuum hole 214. The substrate W may be loaded on the support plate 211. The support plate 211 may horizontally accommodate the substrate W and support the substrate W. A processing liquid may be applied onto the substrate W supported by the support plate 211. The processing liquid may be a photoresist, but is not limited thereto. Hereinafter, it will be described that the processing liquid applied onto the substrate W is a photoresist 270.

The elevating portion 212 may extend in a vertical direction. The vertical direction may be a first direction D1. Herein, the first direction D1 may be a direction perpendicular to an upper surface of the substrate W, and a second direction D2 may be a direction parallel to the upper surface of the substrate W. The first direction D1 and the second direction D2 may cross each other and may be substantially perpendicular to each other.

The elevating portion 212 may move the support plate 211 in the first direction D1. In addition, the elevating portion 212 may be rotatable about an axis in the first direction D1. Accordingly, the support plate 211 may also be rotatable about an axis in the first direction D1. The spin chuck 210 may rotate the support plate 211 by rotating the elevating portion 212 using the driving portion 213. Accordingly, the substrate W seated on the support plate 211 may also be rotated. For example, the spin chuck 210 may rotate the substrate W at a speed of about 1000 rpm to about 1600 rpm, but is not limited thereto. The photoresist 270 applied onto the substrate W may be applied from a center to an edge of the substrate W by centrifugal force. The elevating portion 212 may include, for example, a shaft that is rotatable and that can be extended and contracted (e.g., raised and lowered). For example, the shaft may be raised and lowered using hydraulics, or using an actuator such as a motor, and may be rotated using an actuator such as a motor. The driving portion 213 may include an actuator such as a motor, and/or a hydraulic system, for raising, lowering, and rotating the shaft.

The vacuum hole 214 may be disposed on a lower surface of the substrate W. When a vacuum is applied in the vacuum hole 214, the substrate W may be fixed onto the spin chuck 210. When the substrate W is fixed onto the spin chuck 210 by the vacuum hole 214, the spin chuck 210 may rotate the substrate W.

The photoresist supply portion 220 may supply the photoresist 270 to the photoresist pipe 260 and the nozzle 230. The photoresist supply portion 220 may store the photoresist 270. For example, the photoresist supply portion 220 may include a bottle and/or a reservoir, and may be described as a photoresist supply source. In addition, the photoresist supply portion 220 may include a flow rate control valve for controlling a supply flow rate of the photoresist 270, but the technical spirit of the present disclosure is not limited thereto.

The nozzle 230 may be connected to the nozzle arm 240. The nozzle arm 240 may be disposed adjacent to the spin chuck 210. The nozzle arm 240 may move the nozzle 230 onto the spin chuck 210. The nozzle 230 may provide the photoresist 270 onto the center of the substrate W. The nozzle 230 may be provided at a position spaced apart from the center of the substrate W in the first direction D1. For example, the photoresist 270 may be provided as droplets onto the substrate W. In this case, the photoresist 270 may be continuously applied onto the substrate W.

The elevating mechanism 250 may be connected to the nozzle arm 240. The elevating mechanism 250 may drive the nozzle arm 240. The elevating mechanism 250, also described as an elevating driver, may move the nozzle arm 240 in the first direction D1 and/or the second direction D2 (e.g., by raising and lowering, and rotating). Accordingly, the nozzle 230 may be positioned on the substrate W.

The photoresist pipe 260 connects the nozzle 230 to the photoresist supply portion 220. The photoresist pipe 260 may transfer the photoresist 270 from the photoresist supply portion 220 to the nozzle 230. The photoresist pipe 260 may be opaque to protect the photoresist 270 from external light. When the photoresist pipe 260 is opaque, photosensitization of the photoresist 270 may be prevented or minimized. As an example, the photoresist 270 may include an organic photoresist and an inorganic photoresist. The organic photoresist is mostly used in KrF or ArF ultraviolet (UV) exposure processes, and the inorganic photoresist is mainly used in extreme ultraviolet (EUV) exposure processes. For example, the inorganic photoresist may be a metal photoresist. The inorganic photoresist may include nano-sized metal particles. Since the metal particles combine with atmospheric moisture to easily denaturalize the inorganic photoresist, sealing of the photoresist pipe 260 and the nozzle 230 may be more stringently required.

The recovery cup 215 may be disposed to surround the spin chuck 210. The recovery cup 215 may collect the photoresist 270 scattered from the substrate W by rotation. A liquid outlet 281 is formed at a bottom portion of the recovery cup 215, and the photoresist 270 collected by the recovery cup 215 is discharged to the outside of the chamber 205 through the liquid outlet 281. In addition, an exhaust port 283 may be formed at the bottom portion of the recovery cup 215 to discharge gas supplied into the chamber 205 to the outside of the chamber 205.

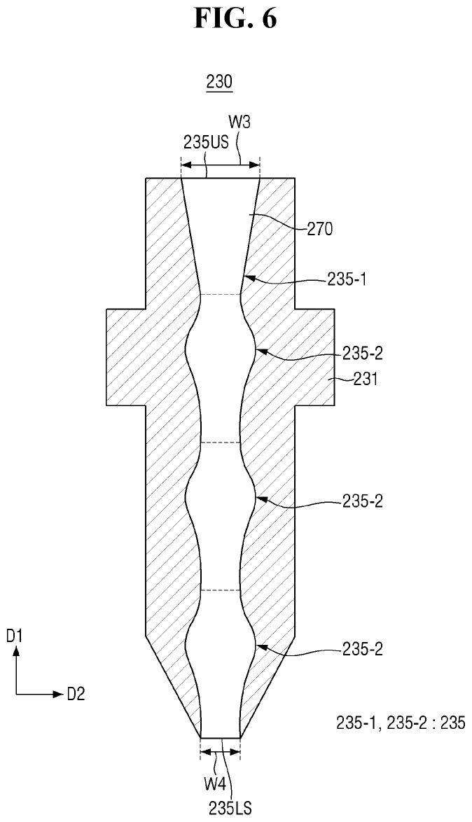

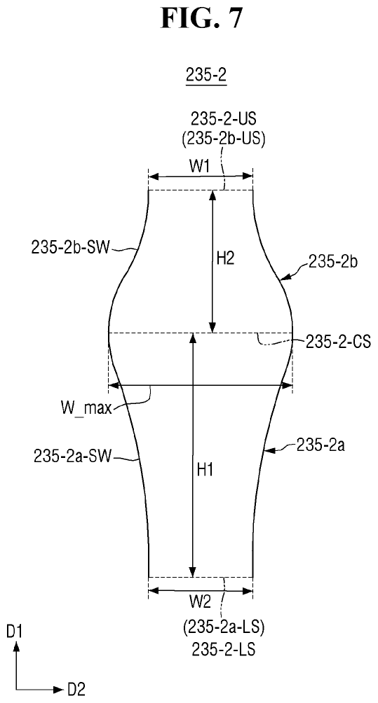

FIG. 6 is an enlarged view for describing a nozzle of FIG. 5. FIG. 7 is an enlarged view for describing a first lower pipe of FIG. 6. Hereinafter, a nozzle according to some exemplary embodiments will be described in more detail with reference to FIGS. 6 and 7.

First, referring to FIG. 6, a nozzle 230 according to some exemplary embodiments may include a housing 231 and a pipe 235.

The pipe 235 may be a passage, also described as an opening, through which the photoresist 270 moves, for example an internal passage within the housing 231. The term “passage” may be used herein to broadly describe the term “pipe” in referring the pipe and the pipe sections described herein. The pipe 235 may be a separate pipe, or series of connected pipes or pipe sections, formed within the housing 231, or may be integrally formed from the material that forms the housing 231, as an opening in the housing 231. The photoresist 270 may be applied onto the substrate W by being moved along and through the pipe 235. The pipe 235 may extend in the first direction D1. Therefore, the photoresist 270 may move in the first direction D1 within the pipe 235. The housing 231 may surround the pipe 235. With the housing 231, the nozzle 230 and the nozzle arm 240 may be coupled to each other, and/or the nozzle 230 and the photoresist pipe 260 may be coupled to each other.

In some exemplary embodiments, the pipe 235 may include an upper pipe 235-1 and at least one or more first lower pipes 235-2.

The upper pipe 235-1, also described as an upper pipe section, may be disposed at the uppermost portion of the pipe 235. At least one or more first lower pipes 235-2, also described as first lower pipe sections, may be disposed below the upper pipe 235-1. At least one or more first lower pipes 235-2 may be disposed at the lowermost portion of the pipe 235. Herein, the “uppermost portion” may be a point farthest from the substrate W, and the “lowermost portion” may be a point closest to the substrate W.

In some exemplary embodiments, a width of the upper pipe 235-1 in the second direction D2 may gradually decrease toward the substrate W. For example, a width of the uppermost end of the upper pipe 235-1 in the second direction D2 is greater than a width of the lowermost end of the upper pipe 235-1 in the second direction D2. The upper pipe 235-1 may have a tapered shape, wherein the width is continuously decreasing from a higher height (e.g., an uppermost end) to a lower height (e.g., a lowermost end) in the second direction D2. However, the technical spirit of the present disclosure is not limited thereto. The uppermost and lowermost ends of each pipe may also be described as an inlet end or opening and an outlet end or opening, or an inlet interface and outlet interface. The uppermost end may also be described as an upper cross-sectional boundary, and the lowermost end may also be described as a lower cross-sectional boundary (e.g., each being a cross-section perpendicular to the first direction D1).

In some exemplary embodiments, the pipe 235 may include the uppermost end 235US and the lowermost end 235LS. The uppermost end 235US of the pipe 235 may be an opening (e.g., cross-sectional opening, or cross-sectional area) through which the photoresist 270 flows into the nozzle 230 (e.g., a nozzle inlet end or nozzle inlet opening). The uppermost end 235US of the pipe 235 may be connected to the photoresist pipe (260 in FIG. 5). The lowermost end 235LS of the pipe 235 may be an opening (e.g., cross-sectional opening, or cross-sectional area) through which the photoresist 270 is discharged from the nozzle 230 (e.g., a nozzle outlet end or nozzle outlet opening). The uppermost end 235US of the pipe 235 may be the uppermost end of the upper pipe 235-1, and the lowermost end 235LS of the pipe 235 may be the lowermost end of the first lower pipe 235-2, but the present disclosure is not limited thereto.

In some exemplary embodiments, a third width W3 of the uppermost end 235US of the pipe 235 in the second direction D2 is greater than a fourth width W4 of the lowermost end 235LS of the pipe 235 in the second direction D2. In addition, the third width W3 of the uppermost end 235US of the pipe 235 in the second direction D2 may be greater than a maximum width (W_max in FIG. 7) of each first lower pipe 235-2. Therefore, even if the flow rate of the photoresist 270 flowing into the pipe 235 decreases, a speed at which the photoresist 270 is applied toward the substrate W may be improved.

In some exemplary embodiments, at least one or more first lower pipes 235-2 may be connected to the upper pipe 235-1. It is illustrated in FIG. 6 that the pipe 235 has three first lower pipes 235-1, but the technical spirit of the present disclosure is not limited thereto. The number of first lower pipes 235-2 may be two or more.

The lowermost end of a first lower pipe 235-2 disposed at the lowermost portion among the plurality of first lower pipes 235-2 may be the lowermost end 235LS of the pipe 235. Therefore, the lowermost end of the first lower pipe 235-2 disposed at the lowermost portion may be an opening through which the photoresist 270 is discharged from the nozzle 230. A width of the first lower pipe 235-2 in the second direction D2 may gradually increase and then decrease toward the substrate W. This will be described in detail with reference to FIG. 7.

Referring to FIG. 7, each first lower pipe 235-2 may include a first portion 235-2a and a second portion 235-2b.

The first portion 235-2a of the first lower pipe 235-2 and the second portion 235-2b of the first lower pipe 235-2 may be aligned to overlap in the first direction D1. For example, the second portion 235-2b of the first lower pipe 235-2 may be disposed on the first portion 235-2a of the first lower pipe 235-2. The first portion 235-2a of the first lower pipe 235-2 may be closer to the substrate W than the second portion 235-2b of the first lower pipe 235-2.

In some exemplary embodiments, the first lower pipe 235-2 may include an uppermost end 235-2-US (e.g., uppermost opening), a lowermost end 235-2-LS (e.g., lowermost opening), and a central opening 235-2-CS (e.g., central cross-section area). The lowermost end 235-2-LS of the first lower pipe 235-2 may face the substrate W. The uppermost end 235-2-US of the first lower pipe 235-2 may be opposite to the substrate W and face away from the substrate. The uppermost end 235-2-US of the first lower pipe 235-2 may be opposite the lowermost end 235-2-LS of the first lower pipe 235-2. The central opening 235-2-CS of the first lower pipe 235-2 may be provided between the uppermost end 235-2-US and the lowermost end 235-2-LS. The central surface 235-2-CS of the first lower pipe 235-2 may be a boundary cross-section between the first portion 235-2a and the second portion 235-2b.

The uppermost end 235-2-US of the first lower pipe 235-2 has a first width W1 in the second direction D2. The lowermost end 235-2-LS of the first lower pipe 235-2 has a second width W2 in the second direction D2. A size of the first width W1 may be the same as that of the second width W2. The central opening 235-2-CS of the first lower pipe 235-2 has a width W_max in the first direction D1. The width W_max of the central opening 235-2-CS may be the maximum width W_max of the first lower pipe 235-2. That is, the first lower pipe 235-2 may have the maximum width W_max at the central opening 235-2-CS. That is, the first lower pipe 235-2 may have the maximum width W_max at the boundary cross-section between the first portion 235-2a and the second portion 235-2b, but is not limited thereto.

The maximum width W_max of the first lower pipe 235-2 may be greater than the first width W1 and the second width W2. The width of the first lower pipe 235-2 may gradually and continually decrease as a distance from the central surface 235-2-CS toward either end increases. The two sides of the first lower pipe 235-2 from a cross-section along a plane formed by the first direction D1 and second direction D2 may have a bow shape, so that the two sides have mirror symmetry, and form a pipe having a larger width in a central section and smaller widths in top and bottom sections.

In some exemplary embodiments, a ratio of the maximum width W_max to the first width W1 may be 1:2 to 1:2.5. That is, the maximum width W_max may be 2 to 2.5 times the first width W1. Similarly, a ratio of the maximum width W_max to the second width W2 may be 1:2 to 1:2.5. The maximum width W_max may be 2 to 2.5 times the second width W2. However, the technical spirit of the present disclosure is not limited thereto.

In some exemplary embodiments, the first portion 235-2a of the first lower pipe 235-2 may have a first height H1 in the first direction D1. The second portion 235-2b of the first lower pipe 235-2 may have a second height H2 in the first direction D1. The first height H1 is greater than the second height H2. For example, a ratio of the second height H2 to the first height H1 may be 2:1 to 3:1. The first height H1 may be two to three times the second height H2. However, the technical spirit of the present disclosure is not limited thereto. The first height H1 may represent a height from a lowermost end 235-2-LS of the first lower pipe 235-2 to a height that has the cross-sectional greatest width of the first lower pipe 235-2, and the second height H2 may represent a height from an uppermost end 235-2-LS of the first lower pipe 235-2 to the height that has the cross-sectional greatest width of the first lower pipe 235-2.

In some exemplary embodiments, a width of the first portion 235-2a of the first lower pipe 235-2 in the second direction D2 may gradually increase as a distance from the substrate W increases. The width of the first portion 235-2a of the first lower pipe 235-2 in the second direction D2 may gradually decrease as the distance from the substrate W decreases. The width of the first portion 235-2a of the first lower pipe 235-2 in the second direction D2 may gradually decrease from the central opening 235-2-CS to the lowermost end 235-2-LS. The width of the first portion 235-2a of the first lower pipe 235-2 in the second direction D2 may gradually increase from the lowermost end 235-2-LS to the central opening 235-2-CS. The width of the first portion 235-2a of the first lower pipe 235-2 in the second direction D2 may be a distance between opposite sidewalls 235-2a-SW of the first portion 235-2a of the first lower pipe 235-2.

In some exemplary embodiments, a slope of the sidewall 235-2a-SW of the first portion 235-2a of the first lower pipe 235-2 may gradually decrease and then increase from the central opening 235-2-CS to the lowermost end 235-2-LS. Therefore, the sidewall 235-2a-SW of the first portion 235-2a of the first lower pipe 235-2 may have an inflection point. Herein, “the slope of A” may refer to an angle formed by A and a reference line extending along the second direction D2.

At the central opening 235-2-CS, the slope of the sidewall 235-2a-SW of the first portion 235-2a of the first lower pipe 235-2 may be substantially 90°. At the lowermost end 235-2-LS, the slope of the sidewall 235-2a-SW of the first portion 235-2a of the first lower pipe 235-2 may be substantially 90°. Between the central opening 235-2-CS and the lowermost end 235-2-LS, the slope of the sidewall 235-2a-SW of the first portion 235-2a of the first lower pipe 235-2 may be smaller than 90°. However, the technical spirit of the present disclosure is not limited thereto.

In some exemplary embodiments, a width of the second portion 235-2b of the first lower pipe 235-2 in the second direction D2 may gradually decrease as a distance from the substrate W increases. The width of the second portion 235-2b of the first lower pipe 235-2 in the second direction D2 may gradually increase as the distance from the substrate W decreases. The width of the second portion 235-2b of the first lower pipe 235-2 in the second direction D2 may gradually decrease from the central opening 235-2-CS to the uppermost end 235-2-US. The width of the second portion 235-2b of the first lower pipe 235-2 in the second direction D2 may gradually increase from the uppermost end 235-2-US to the central opening 235-2-CS. The width of the second portion 235-2b of the first lower pipe 235-2 in the second direction D2 may be a distance between opposite sidewalls 235-2a-SW of the second portion 235-2b of the first lower pipe 235-2.

In some exemplary embodiments, a slope of the sidewall 235-2b-SW of the second portion 235-2-2b of the first lower pipe 235-2 may gradually decrease and then increase from the central opening 235-2-CS to the uppermost end 235-2-US. Therefore, the sidewall 235-2b-SW of the second portion 235-2b of the first lower pipe 235-2 may have an inflection point. At the central opening 235-2-CS, the slope of the sidewall 235-2b-SW of the second portion 235-2b of the first lower pipe 235-2 may be substantially 90°. At the uppermost end 235-2-US, the slope of the sidewall 235-2b-SW of the second portion 235-2b of the first lower pipe 235-2 may be substantially 90°. Between the central opening 235-2-CS and the uppermost end 235-2-US, the slope of the sidewall 235-2b-SW of the second portion 235-2b of the first lower pipe 235-2 may be smaller than 90°. However, the technical spirit of the present disclosure is not limited thereto.

According to some exemplary embodiments, the pipe 235 may include at least one or more first lower pipes 235-2 (e.g., lower pipe sections) whose width increases and then decreases toward the substrate W. Thus, sidewalls of the pipe 235 may form a wave pattern, causing the width of the pipe 235 to have repeatedly increasing and decreasing widths. The sidewalls may have a smooth, continuous structure in some embodiments, or may include connected sections in other embodiments. As the pipe 235 has such a structure, the speed of the photoresist 270 passing through the pipe 235 and applied to the substrate W may be increased. Specifically, even if a smaller amount of the photoresist 270 is supplied, the speed of the photoresist 270 applied to the substrate W may not decrease. Therefore, costs consumed when fabricating a semiconductor device using the substrate processing apparatus of the present disclosure may be reduced.

In some exemplary embodiments, the lowermost end 235-2a-LS of the first portion 235-2a may be the lowermost end 235-2-LS of the first lower pipe 235-2. The uppermost end of the first portion 235-2a may be the central opening 235-2-CS of the first lower pipe 235-2. The lowermost end of the second portion 235-2b may be the central opening 235-2-CS of the first lower pipe 235-2. The uppermost end 235-2b-US of the second portion 235-2b may be the uppermost end 235-2-US of the first lower pipe 235-2. Accordingly, in some embodiments, the second width W2 of the lowermost end 235-2a-LS of the first portion 235-2a is the same as the first width W1 of the uppermost end 235-2b-US of the second portion 235-2b.

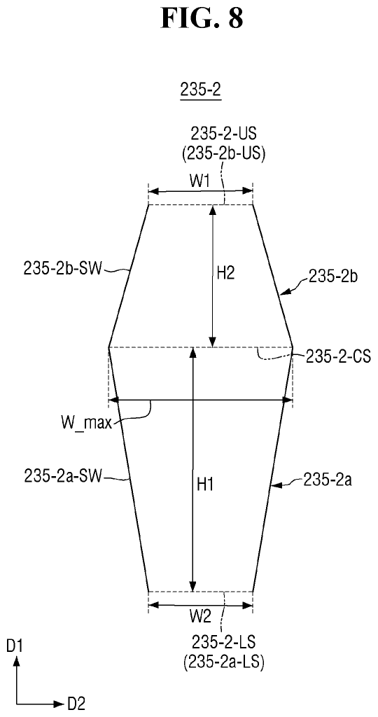

Hereinafter, a substrate processing apparatus according to some other exemplary embodiments will be described with reference to FIGS. 8 to 17. For the convenience of explanation, the contents overlapping those described with reference to FIGS. 1 to 7 will be briefly described or omitted.

FIGS. 8 to 14 are illustrative views for describing a first lower pipe according to some other exemplary embodiments.

Referring to FIG. 8, the slope of the sidewall 235-2a-SW of the first portion 235-2a of the first lower pipe 235-2 may be constant. In addition, the slope of the sidewall 235-2b-SW of the second portion 235-2b of the first lower pipe 235-2 may be constant.

Specifically, while the width of the first portion 235-2a of the first lower pipe 235-2 in the second direction D2 gradually increases from the lowermost end 235-2-LS of the first lower pipe 235-2 toward the central opening 235-2-CS of the first lower pipe 235-2, the slope of the sidewall 235-2a-SW of the first portion 235-2a of the first lower pipe 235-2 may be constant. In this case, the slope of the sidewall 235-2a-SW of the first portion 235-2a of the first lower pipe 235-2 is smaller than 90°. Therefore, in a cross-sectional view, the sidewall 235-2a-SW of the first portion 235-2a of the first lower pipe 235-2 may be straight. In a cross-sectional view, the sidewall 235-2a-SW of the first portion 235-2a of the first lower pipe 235-2 may extend outward from the first direction D1 at any angle, on a plane formed by the intersection of the second direction D2 and the first direction D1.

Specifically, while the width of the second portion 235-2b of the first lower pipe 235-2 in the second direction D2 gradually increases from the lowermost end 235-2-LS of the first lower pipe 235-2 toward the central opening 235-2-CS of the first lower pipe 235-2, the slope of the sidewall 235-2b-SW of the second portion 235-2b of the first lower pipe 235-2 may be constant. In this case, the slope of the sidewall 235-2b-SW of the second portion 235-2b of the first lower pipe 235-2 is smaller than 90°. Therefore, in a cross-sectional view, the sidewall 235-2b-SW of the second portion 235-2b of the first lower pipe 235-2 may be straight. In a cross-sectional view, the sidewall 235-2b-SW of the second portion 235-2b of the first lower pipe 235-2 may extend outward from the first direction D1 at any angle, on a plane formed by the intersection of the second direction D2 and the first direction D1. In the embodiment of FIG. 8, sidewalls of the pipe 235 may form a zig-zag pattern, causing the width of the pipe 235 to have repeatedly increasing and decreasing widths. The sidewalls may have an angled, continuous structure in some embodiments, or may include angled, connected segments in other embodiments.

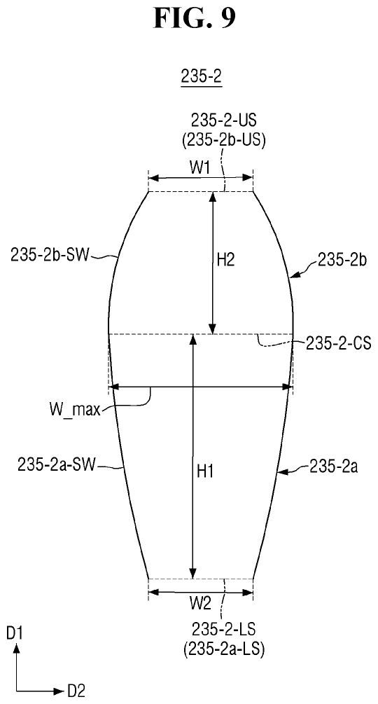

Referring to FIG. 9, the sidewall 235-2a-SW of the first portion 235-2a of the first lower pipe 235-2 does not have an inflection point.

Specifically, both the width of the first portion 235-2a of the first lower pipe 235-2 in the second direction D2 and the slope of the sidewall 235-2a-SW of the first portion 235-2a of the first lower pipe 235-2 may gradually increase from the lowermost end 235-2-LS of the first lower pipe 235-2 toward the central opening 235-2-CS of the first lower pipe 235-2.

The width of the first portion 235-2a of the first lower pipe 235-2 and the slope of the sidewall 235-2a-SW of the first portion 235-2a of the first lower pipe 235-2 may gradually decrease from the central opening 235-2-CS of the first lower pipe 235-2 toward the lowermost end 235-2-LS of the first lower pipe 235-2.

Therefore, the slope of the sidewall 235-2a-SW of the first portion 235-2a of the first lower pipe 235-2 may have a minimum value at the lowermost end 235-2-LS and a maximum value at the central opening 235-2-CS.

The sidewall 235-2b-SW of the second portion 235-2b of the first lower pipe 235-2 does not have an inflection point.

Specifically, both the width of the second portion 235-2b of the first lower pipe 235-2 and the slope of the sidewall 235-2b-SW of the second portion 235-2b of the first lower pipe 235-2 may gradually decrease from the central opening 235-2-CS of the first lower pipe 235-2 toward the uppermost end 235-2-US of the first lower pipe 235-2.

Both the width of the second portion 235-2b of the first lower pipe 235-2 and the slope of the sidewall 235-2b-SW of the second portion 235-2b of the first lower pipe 235-2 may gradually increase from the uppermost end 235-2-US of the first lower pipe 235-2 toward the central opening 235-2-CS of the first lower pipe 235-2.

Therefore, the slope of the sidewall 235-2b-SW of the second portion 235-2b of the first lower pipe 235-2 may have a minimum value at the uppermost end 235-2-US and a maximum value at the central opening 235-2-CS. In this case, the first lower pipe 235-2 may have a maximum width at the central opening 235-2-CS. In the embodiment of FIG. 9, sidewalls of the pipe 235 may form a wave pattern, causing the width of the pipe 235 to have repeatedly increasing and decreasing widths. The sidewalls may have partially curved and partially angled portions in some embodiments.

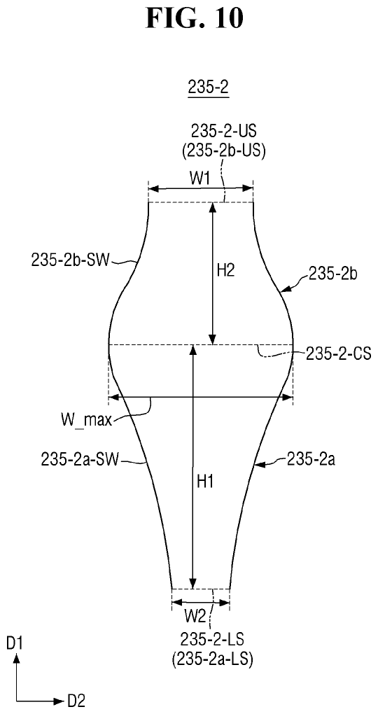

Referring to FIG. 10, the first width W1 of the uppermost end 235-2-US of the first lower pipe 235-2 may be greater than the second width W2 of the lowermost end 235-2-LS of the first lower pipe 235-2. The width of the uppermost end 235-2b-US of the second portion 235-2b of the first lower pipe 235-2 is greater than the width of the lowermost end 235-2a-LS of the first portion 235-2a of the first lower pipe 235-2.

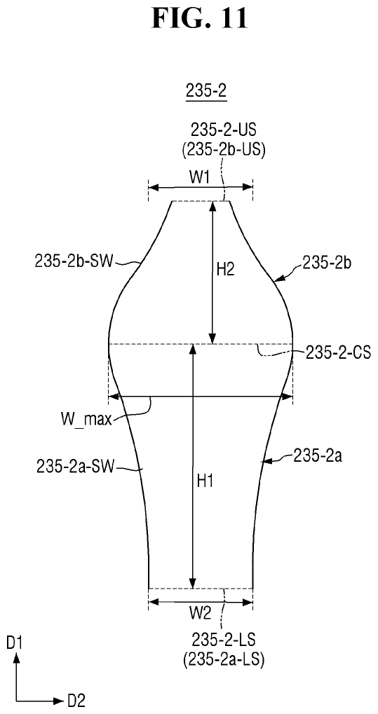

Referring to FIG. 11, the first width W1 of the uppermost end 235-2-US of the first lower pipe 235-2 may be smaller than the second width W2 of the lowermost end 235-2-LS of the first lower pipe 235-2. The width of the uppermost end 235-2b-US of the second portion 235-2b of the first lower pipe 235-2 is smaller than the width of the lowermost end 235-2a-LS of the first portion 235-2a of the first lower pipe 235-2. The embodiments of FIGS. 10 and 11 may be used for a different set of pipe segments from that depicted in FIG. 6, for example, to have a horizontal wall portion where an uppermost end of one first lower pipe 235-2 meets a lowermost end of an adjacent first lower pipe 235-2.

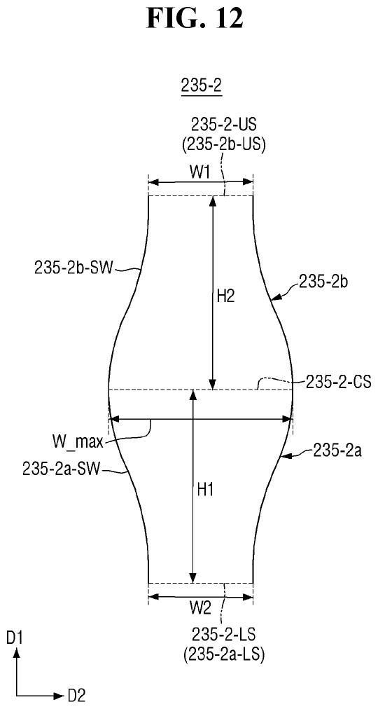

Referring to FIG. 12, the first height H1 and the second height H2 may be equal to each other. For example, the height of the first portion 235-2a of the first lower pipe 235-2 in the first direction D1 may be equal to the height of the second portion 235-2b of the first lower pipe 235-2 in the first direction D1. A ratio of the second height H2 to the first height H1 may be 1:1.

A vertical distance from the lowermost end 235-2-LS of the first lower pipe 235-2 to the central opening 235-2-CS of the first lower pipe 235-2 is equal to a vertical distance from the central opening 235-2-CS of the first lower pipe 235-2 to the uppermost end 235-2-US of the first lower pipe 235-2. Thus, the first portion 235-2a of the first lower pipe 235-2 and the second portion 235-2b of the first lower pipe 235-2 may be symmetrical to each other based on the central opening 235-2-CS. The change in slope in a direction upward from the central opening 235-2-CS may match the change in slope in a direction downward from the central opening 235-2-CS. However, the technical spirit of the present disclosure is not limited thereto.

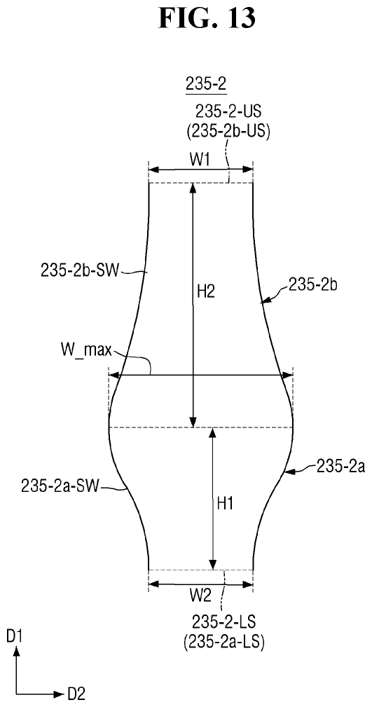

Referring to FIG. 13, the first height H1 may be smaller than the second height H2. That is, the height of the first portion 235-2a of the first lower pipe 235-2 in the first direction D1 may be smaller than the height of the second portion 235-2b of the first lower pipe 235-2 in the first direction D1.

A minimum value of the slope of the sidewall 235-2a-SW of the first portion 235-2a of the first lower pipe 235-2 in this embodiment is smaller than a minimum value of the slope of the sidewall 235-2b-SW of the second portion 235-2b of the first lower pipe 235-2, but the present disclosure is not limited thereto.

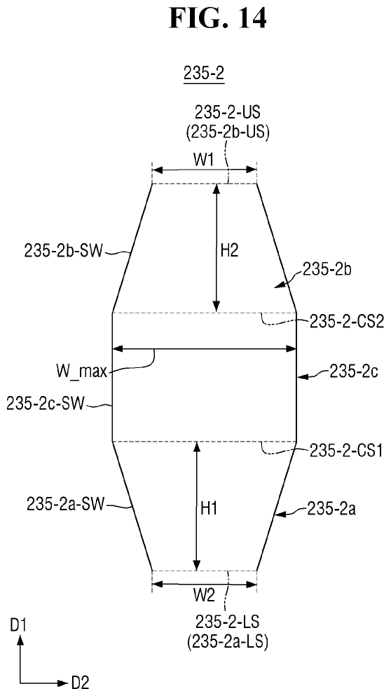

Referring to FIG. 14, the first lower pipe 235-2 according to some exemplary embodiments may further include a third portion 235-2c.

The third portion 235-2c may be disposed between the first portion 235-2a and the second portion 235-2b. For example, the second portion 235-2a may be disposed above the third portion 235-2c. The first portion 235-2a may be disposed under the third portion 235-2c.

In some exemplary embodiments, a width of the third portion 235-2c of the first lower pipe 235-2 in the second direction D2 may be constant. For example, the width of the third portion 235-2c of the first lower pipe 235-2 in the second direction D2 is constant from the first portion 235-2a toward the second portion 235-2b.

In some exemplary embodiments, the height H1 of the first portion 235-2a of the first lower pipe 235-2 in the first direction D1 may be equal to the height H2 of the second portion 235-2b of the first lower pipe 235-2 in the first direction D1. That is, the first portion 235-2a of the first lower pipe 235-2 and the second portion 235-2b of the first lower pipe 235-2 may be symmetrical to each other based on the third portion 235-2c. However, the technical spirit of the present disclosure is not limited thereto. The first height H1 and the second height H2 may also be different from each other.

In some exemplary embodiments, the central opening of the first lower pipe 235-2 may include a first central opening 235-2-CS1 and a second central opening 235-2-CS2. The first central opening 235-2-CS1 may be provided between the lowermost end 235-2-LS of the first lower pipe 235-2 and the second central opening 235-2-CS2. The second central opening 235-2-CS2 may be provided between the uppermost end 235-2-US of the first lower pipe 235-2 and the first central opening 235-2-CS1. The first central opening 235-2-CS1 may be a lowermost end of the third portion 235-2c, and the second central opening 235-2-CS2 may be an uppermost end of the third portion 235-2c.

A vertical distance from the lowest end 235-2-LS of the first lower pipe 235-2 to the first central opening 235-2-CS1 may be equal to a vertical distance from the second central opening 235-2-CS2 to the uppermost end 235-2-US of the first lower pipe 235-2, but the present disclosure is not limited thereto.

The maximum width W_max of the first lower pipe 235-2 may be a width of the third portion 235-2c in the second direction D2. The maximum width W_max of the first lower pipe 235-2 may be a width of the first central opening 235-2-CS1 in the second direction D2. The maximum width W_max of the first lower pipe 235-2 may be a width of the second central opening 235-2-CS2 in the second direction D2. However, the technical spirit of the present disclosure is not limited thereto.

In some exemplary embodiments, a slope of a sidewall 235-2c-SW of the third portion 235-2c may be constant. For example, the slope of the sidewall 235-2c-SW of the third portion 235-2c may be 90°. The sidewall 235-2c-SW of the third portion 235-2c may extend in the first direction D1.

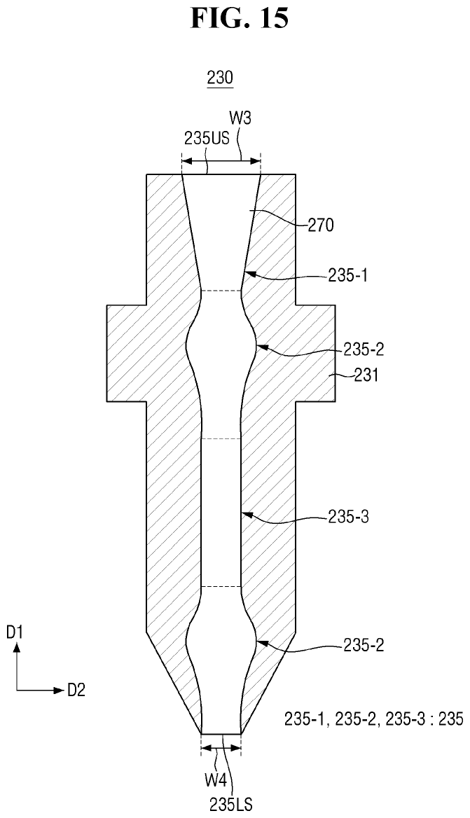

FIGS. 15 to 17 are views for describing a nozzle according to some other exemplary embodiments.

Referring to FIG. 15, the pipe 235 of the nozzle 230 according to some exemplary embodiments may further include a second lower pipe 235-3 (e.g., second lower pipe section).

The second lower pipe 235-3 may be disposed between the first lower pipes 235-2. The second lower pipe 235-3 may be connected to the first lower pipes 235-2. For example, one end of the second lower pipe 235-3 may be connected to the first lower pipe 235-2, and the other end of the second lower pipe 235-3 may be connected to the other first lower pipe 235-2.

However, the technical spirit of the present disclosure is not limited thereto, and the second lower pipe 235-3 may also be disposed between the upper pipe 235-1 and the first lower pipe 235-2. In this case, one end of the second lower pipe 235-3 may be connected to the upper pipe 235-1, and the other end of the second lower pipe 235-3 may be connected to the first lower pipe 235-2. Alternatively, the second lower pipe 235-3 may also be disposed at the lowermost portion of the pipe 235.

In some exemplary embodiments, a width of the second lower pipe 235-3 in the second direction D2 may be constant. For example, the width of the second lower pipe 235-3 in the second direction D2 may be the same as the first width (W1 in FIG. 7) of the uppermost end of the first lower pipe 235-2. Alternatively, or additionally, the width of the second lower pipe 235-3 in the second direction D2 may be the same as the second width (W2 in FIG. 7) of the lowermost end of the first lower pipe 235-2.

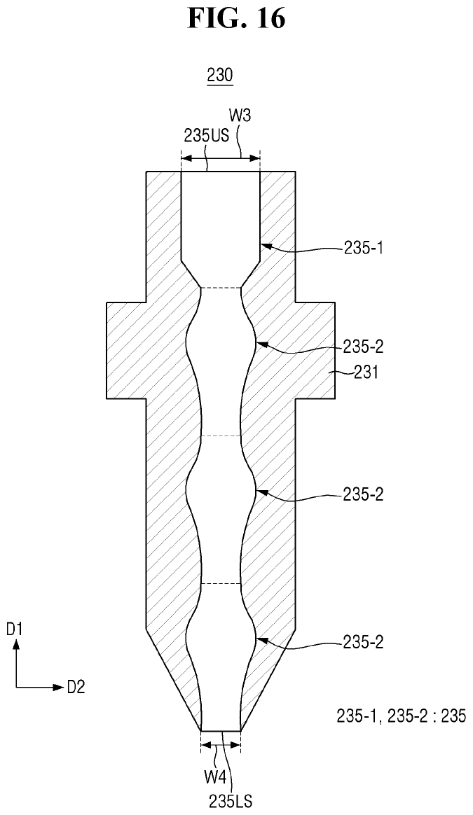

Referring to FIG. 16, an upper pipe 235-1 according to some exemplary embodiments may include a portion having a constant width toward the substrate W. For example, the upper pipe 235-1 may include a portion having a constant width toward the substrate W and a portion having a reduced width toward the substrate W. Even in this case, a width of the uppermost end 235US of the upper pipe 235-1 is greater than a width of the lowermost end 235LS of the pipe 235.

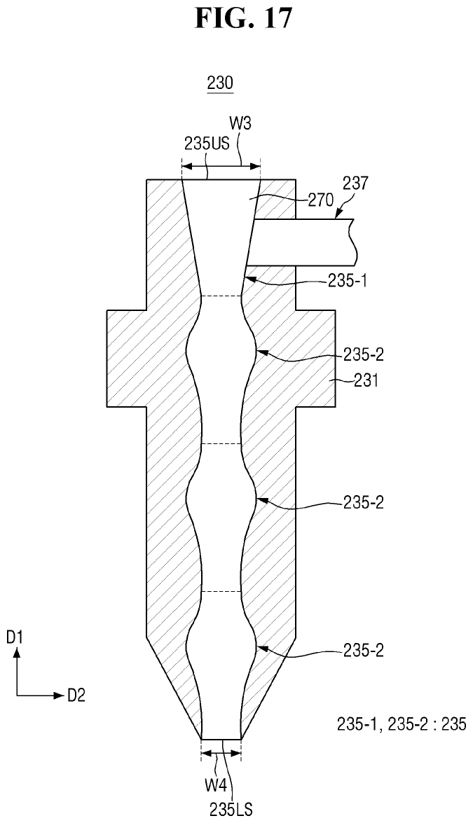

Referring to FIG. 17, a nozzle 230 according to some exemplary embodiments may further include an additional pipe 237. The additional pipe 237 may be connected to the pipe 235. The additional pipe 237 may extend in the second direction D2. The additional pipe 237 may be connected to the sidewall of the pipe 235.

Specifically, the additional pipe 237 may be connected to the upper pipe 235-1 of the pipe 235. The additional pipe 237 may be a passage through which a processing liquid and/or a processing gas other than the photoresist 270 move. A processing liquid and/or a processing gas other than the photoresist 270 may be supplied into the chamber (205 in FIG. 5) through the additional pipe 237.

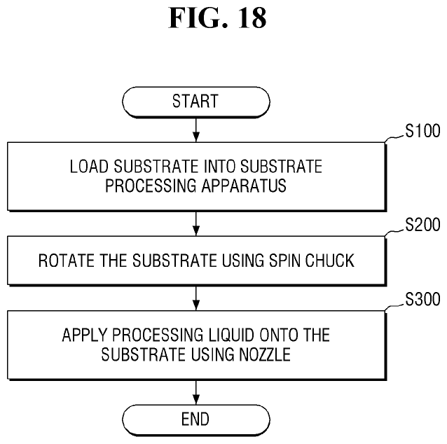

Hereinafter, a method for fabricating a semiconductor device according to some exemplary embodiments will be described with reference to FIGS. 18 to 22. For the convenience of explanation, the contents overlapping those described with reference to FIGS. 1 to 7 will be briefly described or omitted.

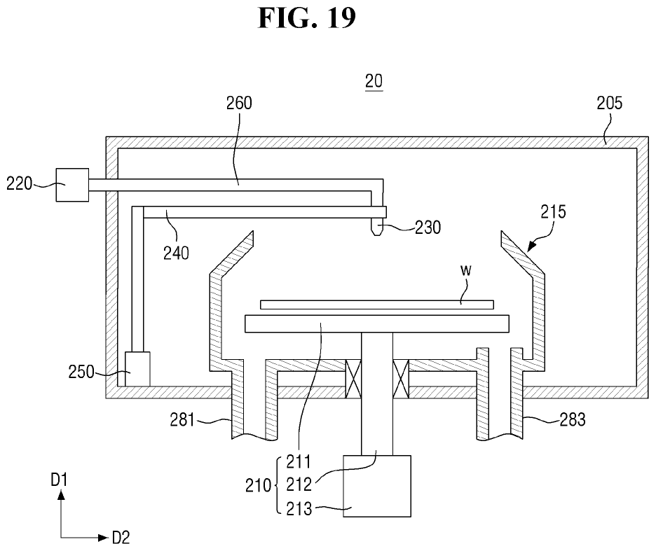

FIG. 18 is a flowchart for describing a method for fabricating a semiconductor device according to some exemplary embodiments. FIGS. 19 to 21 are intermediate step views for describing the method for fabricating the semiconductor device according to some exemplary embodiments.

First, referring to FIG. 18, a method for fabricating a semiconductor device according to some exemplary embodiments may include loading a substrate into a substrate processing apparatus (S100), rotating the substrate using a spin chuck (S200), and applying a processing liquid onto the substrate using a nozzle (S300). The processing liquid may be a photoresist.

Specifically, referring to FIGS. 18 and 19, the substrate W may be loaded into the substrate processing apparatus (S100). The substrate processing apparatus may be the spin unit 20, but is not limited thereto. The substrate W may be loaded into the chamber 205 of the spin unit 20. The substrate W may be seated on the spin chuck 210. The spin chuck 210 may accommodate the substrate W.

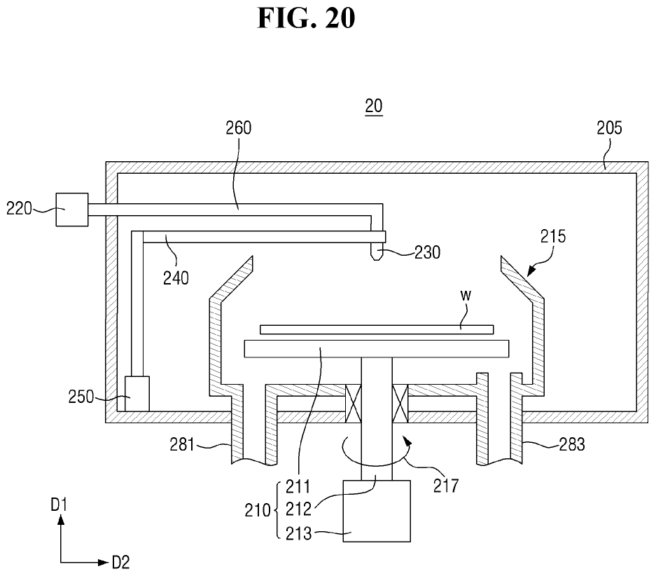

Referring to FIGS. 18 and 20, the substrate W may be rotated using the spin chuck 210 (S200). When the substrate W is accommodated on the support plate 211 of the spin chuck 210, the driving portion 213 may lift the elevating portion 212 in the first direction D1. Subsequently, the driving portion 213 may rotate the elevating portion 212 (see reference number 217). The elevating portion 212 may be rotated about an axis in the first direction D1. It is illustrated that the elevating portion 212 is rotated counterclockwise about an axis in the first direction D1, but the present disclosure is not limited thereto. The elevating portion 212 may also be rotated clockwise about an axis in the first direction D1

As the elevating portion 212 rotates, the support plate 211 may rotate. Accordingly, the substrate W may be rotated. The spin chuck 210 may rotate the substrate W at a speed of about 1000 rpm to about 1600 rpm, but is not limited thereto.

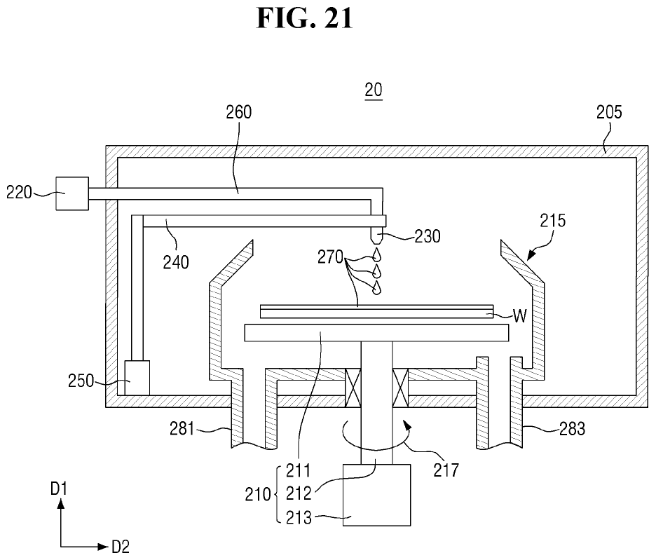

Referring to FIGS. 18 and 21, the nozzle 230 may apply a photoresist 270 onto the substrate W (S300).

First, the elevating mechanism 250 may drive the nozzle arm 240. The elevating mechanism 250 may move the nozzle arm 240 in the first direction D1 and/or the second direction D2. Accordingly, the nozzle 230 may be positioned on the substrate W. In this case, the nozzle 230 may be placed on a central portion of the substrate W.

Subsequently, the nozzle 230 may apply the photoresist 270 onto the substrate W. The photoresist 270 may be continuously applied onto the substrate W. The photoresist 270 applied onto the substrate W may be applied from a center to an edge of the substrate W by centrifugal force.

In some exemplary embodiments, a volume of the photoresist 270 applied onto the substrate W to coat the entire substrate may be 3 mL or less. Preferably, the volume of the photoresist 270 applied onto the substrate W to coat the entire substrate may be 1.5 mL or less. However, the technical spirit of the present disclosure is not limited thereto.

In some exemplary embodiments, a rate of the photoresist 270 applied onto the substrate W may be 1.3 mL/s or less, but is not limited thereto. When the substrate processing apparatus according to some exemplary embodiments of the present disclosure is used, a small amount of photoresist may be effectively applied onto the substrate W to coat the entire substrate. The reason may be due to a shape of the pipe 235.

The above processes may be automatically controlled and implemented using a computer system, which may include microprocessors, memory, computer program code, input/output devices, and other known components programmable to implement the various steps. An operator may set various parameters for the processes.

In addition, subsequent to the photoresist application process described above, remaining steps of a photolithography process may be carried out, using for example, a mask and an exposure process, to form a pattern on the substrate. Other processes may be executed as well, as described in the Background section above, to form various patterns and layers on a substrate. For example, the various patterns and layers may form a semiconductor device such as a memory chip or logic chip.

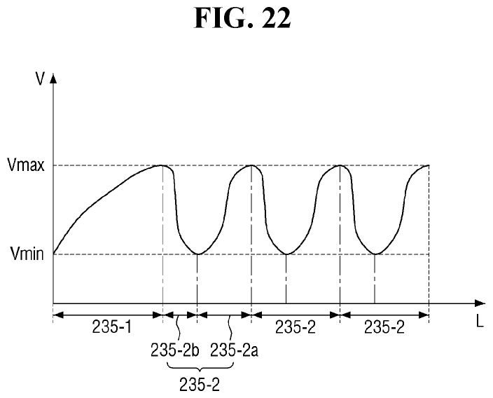

As described above, the pipe 235 according to some exemplary embodiments may include at least one or more lower pipe sections whose widths gradually increase and then decrease toward the substrate W. Due to the structure in which the width of the lower pipe sections change toward the substrate W, the speed of the photoresist flowing in the lower pipe sections may be higher even if the photoresist is supplied at the same flow rate as in existing nozzle pipes used for the same processes. This will be described in more detail with reference to FIG. 22.

FIG. 22 is an illustrative graph illustrating a speed of a photoresist according to a distance of a pipe. In FIG. 22, an x-axis represents a distance of a pipe, and a y-axis represents a speed of the photoresist.

Referring to FIGS. 6, 7, and 22, the speed of the photoresist 270 gradually increases when the photoresist 270 passes through the upper pipe 235-1. Then, when the photoresist 270 passes through the first lower pipe 235-2, the speed of the photoresist 270 may gradually decrease and then increase again. Specifically, when the photoresist 270 passes through the second portion 235-2b of the first lower pipe 235-2, the speed thereof gradually decreases, and may decrease at a rate faster than the rate of increase when the photoresist 270 passes through the upper pipe 235-1. When the photoresist 270 passes through the first portion 235-2a of the first lower pipe 235-2, the speed thereof gradually increases. The rate of increase through the first portion 235-2a may be slower than the rate of decrease through the second portion 235-2b.

The photoresist 270 may have a maximum speed Vmax when passing through a narrow section. Therefore, when the photoresist 270 passes through the uppermost end 235-2-US of the first lower pipe 235-2 or passes through the lowermost end 235-2-LS of the first lower pipe 235-2, the photoresist 270 may have the maximum speed Vmax. On the other hand, the photoresist 270 may have a minimum speed Vmin when passing through a wide section. Therefore, when the photoresist 270 passes the central opening 235-2-CS of the first lower pipe 235-2, the photoresist 270 may have the minimum speed Vmin.

In summary, when the substrate processing apparatus according to some exemplary embodiments of the present disclosure is used, the photoresist of a small flow rate may be effectively applied onto the substrate W. Accordingly, costs may be reduced when fabricating a semiconductor device using the substrate processing apparatus according to some exemplary embodiments of the present disclosure.

In concluding the detailed description, those skilled in the art will appreciate that many variations and modifications may be made to the preferred embodiments without substantially departing from the principles of the present disclosure. Therefore, the disclosed embodiments of the disclosure are used in a generic and descriptive sense only and not for purposes of limitation.

1. A substrate processing apparatus comprising:
a spin chuck that accommodates a substrate and is rotating around a central axis extending in a first direction; and
a nozzle applying a processing liquid onto the substrate,
wherein the nozzle includes a pipe extending in the first direction and through which the processing liquid moves, and a housing surrounding the pipe, and
wherein the pipe includes one or more first lower pipe sections, each of whose width in a second direction intersecting the first direction increases and then decreases in a direction toward the substrate.

2. The substrate processing apparatus of claim 1, wherein for each of the one or more first lower pipe sections, a width of an uppermost end of the first lower pipe section in the second direction and a width of a lowermost end of the first lower pipe section in the second direction are equal to each other.

3. (canceled)

4. The substrate processing apparatus of claim 1, wherein for each of the one or more first lower pipe sections,
the first lower pipe section includes a first portion and a second portion on the first portion,
a width of the first portion in the second direction increases as a distance from the substrate increases, and
a width of the second portion in the second direction decreases as a distance from the substrate increases.

5. The substrate processing apparatus of claim 4, wherein for each of the one or more first lower pipe sections, the first lower pipe section has a maximum width at a boundary between the first portion and the second portion.

6. The substrate processing apparatus of claim 4, wherein a first height of the first portion in the first direction is greater than a second height of the second portion in the first direction.

7. The substrate processing apparatus of claim 6, wherein a ratio of the first height to the second height is from 2:1 to 3:1.

8. The substrate processing apparatus of claim 1, wherein for each of the one or more first lower pipe sections, a ratio of a maximum width of the first lower pipe section in the second direction to a first width of an uppermost end of the first lower pipe section in the second direction is 2:1 to 2.5:1.

9. The substrate processing apparatus of claim 1, further comprising applying the processing liquid onto the substrate at a volume of is 3 mL or less to coat the entire substrate.

10. (canceled)

11. The substrate processing apparatus of claim 1, wherein the pipe includes a second lower pipe section connected to the one or more first lower pipe sections and having a constant width in the second direction toward the substrate.

12. The substrate processing apparatus of claim 1, wherein a width of an uppermost end of the pipe in the second direction is greater than a width of a lowermost end of the pipe in the second direction.

13. (canceled)

14. A substrate processing apparatus comprising:
a spin chuck accommodating a substrate and rotating the substrate; and
a nozzle applying a processing liquid onto the substrate,
wherein the nozzle includes a passage through which the processing liquid moves, and a housing surrounding the passage,
wherein the passage includes a plurality of lower passage sections,
wherein each of the plurality of lower passage sections includes an uppermost end into which the processing liquid is introduced, a lowermost end through which the processing liquid is discharged, and a central opening between the uppermost and lowermost ends, and
wherein a width of the central opening is greater than a width of the uppermost end and is greater than a width of the lowermost end.

15. The substrate processing apparatus of claim 14, wherein the width of the uppermost end of the lower passage sections and the width of the lowermost end of the lower passage sections are equal to each other.

16. The substrate processing apparatus of claim 14, wherein for each lower passage section, a height from the lowermost end of the lower passage section to the central opening of the lower passage section is greater than a height from the central opening of the lower passage section to the uppermost end of the lower passage section.

17. The substrate processing apparatus of claim 14, wherein a width of an uppermost end of the passage is greater than the width of the uppermost end of each lower passage section.

18. The substrate processing apparatus of claim 14, wherein for each lower passage section, a width of the lower passage section gradually increases from the lowermost end toward the central opening, and
the width of the lower passage section gradually decreases from the central opening toward the uppermost end.

19. A substrate processing apparatus comprising:
a chamber defining a processing space;
a spin chuck disposed in the chamber to accommodate a substrate and to be rotatable about axis in a first direction;
a nozzle applying a photoresist onto the substrate; and
a photoresist supply portion supplying the photoresist to the nozzle from a photoresist supply source,
wherein the nozzle includes a pipe extending in the first direction and through which the photoresist moves, and a housing surrounding the pipe,
wherein the pipe includes one or more first lower pipe sections whose widths in a second direction intersecting the first direction increase and then decrease toward the substrate,
wherein each first lower pipe section includes a first portion and a second portion on the first portion, a width of the first portion in the second direction increasing as a distance from the substrate increases, and a width of the second portion in the second direction decreasing as a distance from the substrate increases,
wherein a first height of the first portion in the first direction is greater than a second height of the second portion in the first direction,
wherein a width of an uppermost end of the first portion is equal to a width of a lowermost end of the second portion, and
wherein a width of an uppermost end of the pipe is smaller than a width of a lowermost end of the pipe.

20. The substrate processing apparatus of claim 19, wherein each first lower pipe section has a maximum width at a boundary between the first portion and the second portion.

21. The substrate processing apparatus of claim 19, wherein a ratio of a maximum width of each first lower pipe section to a width of an uppermost end of the first lower pipe is 2:1 to 2.5:1.

22. The substrate processing apparatus of claim 19, further comprising applying the photoresist onto the substrate at a volume of 3 mL or less to coat the entire substrate.

23. The substrate processing apparatus of claim 19, wherein the pipe includes a second lower pipe section connected to the one or more first lower pipe sections and having a constant width in the second direction toward the substrate.

24. The substrate processing apparatus of claim 19, wherein the photoresist is continuously applied onto the substrate to coat the entire substrate.

25-30. (canceled)
